(19) United States
(12) Patent Application Publication
(10) Pub. No.: US 2023/0238595 A1
(43) Pub. Date: Jul. 27, 2023

(54) PHOTOVOLTAIC-ELECTROCHROMIC-BATTERY ALL-IN-ONE DEVICE

(71) Applicant: INDUSTRIAL COOPERATION FOUNDATION JEONBUK NATIONAL UNIVERSITY, Jeonju-si Jeollabuk-do (KR)

(72) Inventors: Ki Tae Lee, Jeonju-si Jeollabuk-do (KR); Yoon Tae Park, Jeonju-si Jeollabuk-do (KR)

(21) Appl. No.: 18/001,228

(22) PCT Filed: Apr. 27, 2021
(86) PCT No.: PCT/KR2021/005315

§ 371 Date: Dec. 8, 2022

(30) Foreign Application Priority Data
Jun. 9, 2020 (KR) 10-2020-0069871

(51) Int. Cl. H01M 10/46; G02F 1/155; G02F 1/163; G02F 1/153; G02F 1/1524; G02F 1/1506; H01G 9/20; H01M 10/0525; H01M 10/0562

(52) U.S. Cl. CPC H01M 10/465; G02F 1/155; G02F 1/163; G02F 1/1533; G02F 1/1524; G02F 1/1506; H01G 9/2059; H01G 9/2031; H01M 10/0525; H01M 10/0562; H01M 2300/0068

(57) ABSTRACT

Disclosed is a photovoltaic-electrochromic-battery all-in-one device in which the functions of a dye-sensitized solar cell, an electrochromic device, and a lithium secondary battery are fused into one device. The all-in-one device according to the disclosure includes a photoelectrode uses as an active layer of a dye-sensitized solar cell (DSSC), a counter electrode used as an electrochromic layer opposite to the photoelectrode, and an electrolyte containing a lithium salt. The all-in-one device according to the disclosure allows the function of the DSSC that generates electrons by receiving solar energy, the function of an electrochromic device (ECD) that blocks light by discoloring an electrode with generated electrons, and the function of a lithium secondary battery (LIB) that stores generated electrons and uses the stored electrons again to be all implemented by one device.

### TECHNOLOGY FIELD

The disclosure relates to an electronic device, and more particularly to a photovoltaic-electrochromic-battery all-in-one device in which the functions of a dye-sensitized solar cell, an electrochromic device, and a lithium secondary battery are fused into one device.

### BACKGROUND ART

With the progress of industrialization and improvement in economic standard, the necessity for using solar energy as clean and infinite resource has been increasing. Solar energy is socially attracting attention as an energy source to replace fossil fuels that are the main culprit of environmental pollution. Accordingly, research and development on various devices utilizing the solar energy, for example, solar cells, electrochromic devices, etc. are being actively conducted.

Recently, research and development on fusion devices for both energy production and storage based on the solar energy are also conducted. The fusion devices are applied to an active radio frequency identification (RFID) sensor, a display, a smart window, etc.

The fusion device has a form in which a solar cell, an electrochromic device, a secondary battery, a supercapacitor and the like device using an electrochemical reaction are fused. The existing fusion device is based on physical coupling between an energy production device and an energy storage device, and therefore resistance in an external circuit contact portion causes efficiency to be lowered.

Although fusion devices having dual functions, for example, a solar cell/electrochromic device, an electrochromic device/super capacitor, an electrochromic device/secondary battery have recently been introduced, they have a disadvantage in that it is difficult to use one function while another function is operating.

Korean Patent Publication No. 10-2017-0044982 has disclosed an electrochromic device with a secondary battery function, in which the functions of the solar cell, the electrochromic device, and the secondary battery are fused. However, such an electrochromic device with a secondary battery function has a structure where the solar cell, the electrochromic device and the secondary battery are horizontally arranged on the same plane, and therefore there is a problem that the area of the device is large even though the device is the fusion device. Further, the electrochromic device with the secondary battery implements three functions, but it is impossible to implement three functions in one structure like a single device because the electrochromic device operates alone.

### DETAILED DESCRIPTION OF THE INVENTION

### Technical Challenge

An aspect of the disclosure is to provide a photovoltaic-electrochromic-battery all-in-one device capable of implementing three functions through one structure like a single device.

Another aspect of the disclosure is to provide a photovoltaic-electrochromic-battery all-in-one device that produces electric energy by receiving solar energy and blocks infrared rays to enhance an energy efficiency during the day, and allows the stored electric energy to be used to maximize an energy saving effect during the night.

### Technical Solution

In accordance with an embodiment, there is provided a photovoltaic-electrochromic-battery all-in-one device including: a photoelectrode formed with an active layer containing metal oxide coated with a dye on a first surface thereof; a counter electrode opposite to the photoelectrode and formed with an electrochromic layer on a surface facing the active layer; and an electrolyte containing a lithium salt filled between the photoelectrode and the counter electrode.

The active layer of the photoelectrode may generate electrons with solar energy incident on a second surface opposite to the first surface and provides the generated electrons to the counter electrode through an external charging circuit, and the electrochromic layer of the counter electrode may perform an electrochromic operation while storing the electrons.

Upon connecting a load between the photoelectrode and the counter electrode through an external discharging circuit, the electrons stored in the electrochromic layer may be provided to the load through the discharging circuit.

The photoelectrode may include a first transparent substrate having light transmittance; a first transparent electrode layer formed on a first surface of the first transparent substrate facing the counter electrode; and the active layer formed on the first transparent electrode layer.

The active layer may include the dye of Ru-dye, and the metal oxide of titanium oxide (TiO₂).

The active layer may be formed by screen-printing the metal oxide coated with the dye on the first transparent electrode layer.

The counter electrode may include: a second transparent substrate having light transmittance; a second transparent electrode layer formed on a first surface of the second transparent substrate facing the photoelectrode; and the electrochromic layer formed on the second transparent electrode layer.

The electrochromic layer may include a structure where a tungsten oxide (WO₃) layer and a platinum (Pt) layer are stacked.

The electrochromic layer may include: the tungsten oxide (WO₃) layer formed being electro-deposited on the second transparent electrode layer; and the platinum (Pt) layer formed being sputtered on the tungsten oxide (WO₃) layer.

The lithium salt may include at least one selected from a group consisting of LiI, LiCl, LiPF₆, LiBF₄, LiSbF₆, LiAsF₆, LiClO₄, LiCF₃SO₃, LiN(CF3₃O₂)₂, LiN(C₂F₅SO₂)₂, LiAlO₄, LiAlCl₄, LiN(CₓF₂ₓ₊₁SO₂)(C_{y}F2ₓ₊₁SO₂) (where, x and y are natural numbers), and LiSO₃OF₃.

### BRIEF DESCRIPTION OF THE DRAWINGS

FIG. 1 is a cross sectional view of a photovoltaic-electrochromic-battery all-in-one device according to an embodiment of the disclosure.

FIG. 2 is a view showing a state that the all-in-one device of FIG. 1 produces and stores electric energy by receiving solar energy and performs an electrochromic operation.

FIG. 3 is a view showing a state that the all-in-one device of FIG. 1 uses the stored electric energy.

FIG. 4 is a photograph showing an electrochromic performance evaluation result of a photovoltaic-electrochromic-battery all-in-one device according to an embodiment of the disclosure.

FIG. 5 is a graph showing an electrochromic performance evaluation result of a photovoltaic-electrochromic-battery all-in-one device according to an embodiment of the disclosure.

FIG. 6 is a graph showing a solar cell performance evaluation result of a photovoltaic-electrochromic-battery all-in-one device according to an embodiment of the disclosure.

FIG. 7 is a graph showing a battery performance evaluation result of a photovoltaic-electrochromic-battery all-in-one device according to an embodiment of the disclosure.

### MODE FOR CARRYING OUT THE INVENTION

In the following description, only parts necessary for understanding embodiments of the disclosure will be described, and it is noted that descriptions of other parts may be omitted within the scope not departing from the gist of the disclosure.

Terms or words used in this specification and claims set forth herein should not be construed as being limited to conventional or lexical meaning, but be construed as meanings and concepts consistent with the technical spirit of the disclosure on the principle that the inventor can appropriately define the terms to explain his/her invention in the best way. Therefore, the embodiments described in this specification and the configurations illustrated in the drawings are merely the exemplary embodiments of the disclosure and do not represent all the technical ideas of the disclosure, and thus it should be appreciated that there may be various equivalents and modifications at the filing date of the present application.

Below, embodiments of the disclosure will be described in more detail with reference to the accompanying drawings.

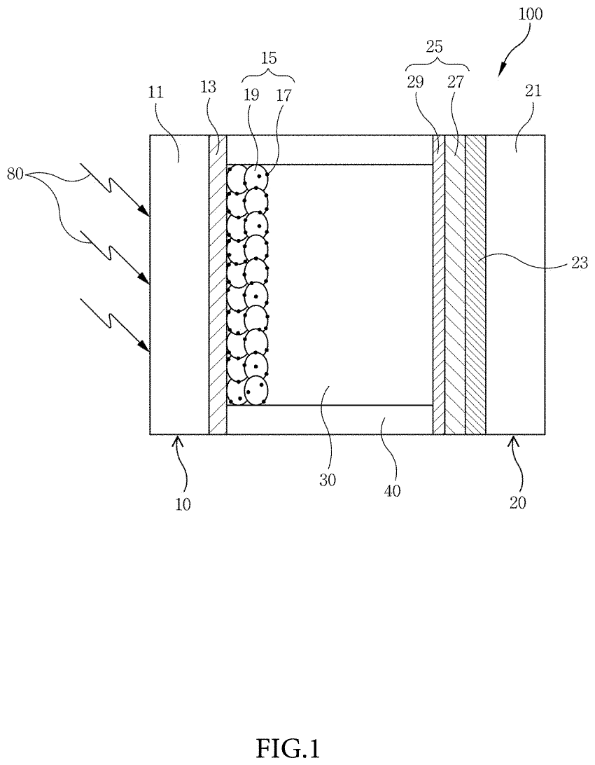

FIG. 1 is a cross sectional view of a photovoltaic-electrochromic-battery all-in-one device according to an embodiment of the disclosure.

Referring to FIG. 1, a photovoltaic-electrochromic-battery all-in-one device 100 according to an embodiment (hereinafter referred to as an ‘all-in-one device’) refers to a fusion device in which the function of a dye-sensitized solar cell (DSSC) that generates electrons by receiving solar energy 80, the function of an electrochromic device (ECD) that blocks light by discoloring an electrode with generated electrons, and the function of a lithium secondary battery (LIB) that stores generated electrons and uses the stored electrons again are all implemented by one device.

The all-in-one device 100 according to the embodiment includes a photoelectrode 10, a counter electrode 20, and an electrolyte 30. The photoelectrode 10 is formed with an active layer 15 containing metal oxide 19 coated with a dye 17 on a first surface thereof. The counter electrode 20 is opposite to the photoelectrode 10 and formed with an electrochromic layer 25 facing the active layer 15. Further, the electrolyte 30 contains a lithium salt filled between the photoelectrode 10 and the counter electrode 20. Besides, the all-in-one device 100 may further include a sealing layer 40.

Below, such elements of the all-in-one device 100 according to an embodiment will be described in detail.

The photoelectrode 10 includes the active layer 15 of the DSSC. The photoelectrode 10 is used as an anode of the lithium secondary battery. The active layer 15 performs an anode active material function of the anode. The photoelectrode 10 includes a first transparent substrate 11, a first transparent electrode layer 13, and the active layer 15. The first transparent substrate 11 has light transmittance. The first transparent electrode layer 13 is formed on a first surface of the first transparent substrate 11 facing the counter electrode 20. Further, the active layer 15 is formed on the first transparent electrode layer 13.

Here, a transparent inorganic substrate or a transparent plastic substrate, which has light transmittance, may be used as the first transparent substrate 11. For the material of the transparent inorganic substrate, glass or quartz may be used. For the material of the transparent plastic substrate, polycarbonate, polystyrene, polyethylene terephthalate (PET), polypropylene, polyethylene naphathalate (PEN), and the like may be used.

The first transparent electrode layer 13 refers to a current collecting layer of the photoelectrode 10, which has light transmittance. For a material of the first transparent electrode layer 13, indium tin oxide (ITO), fluorine-doped tin oxide (FTO), ZnO—Ga₂O₃, ZnO—Al₂O₃, SnO₂—Sb₂O₃, and the like may be used.

Further, the active layer 15 contains the metal oxide 19 coated with the dye 17. The active layer 15 may be formed by screen-printing the metal oxide 19 coated with the dye 17 on the first transparent electrode layer 13.

As the dye 17 absorbs sunlight, an electron-hole pair is formed by electron transition from a ground state to an excited state, and the electron in the excited state is injected into the active layer 15 and transferred to the first transparent electrode layer 13, thereby generating an electromotive force.

The dye 17 may use any material without limitations as long as it is generally used in the field of solar cells, but may use Ru-dye or the like ruthenium complex. Besides Ru-dye, the dye 17 may use xanthine-based pigments such as rhodamine B, rose bengal, eosin, and erythrosine; cyanine-based pigments such as quinocyanine and cryptocyanin; basic dyes such as phenosafranin, carbi blue, thiosine and methylene blue; porphyrin-based compounds such as chlorophyll, zinc porphyrin, and magnesium porphyrin; other azo pigments; phthalocyanine compounds; complex compounds such as Ru trisbipyridyl; anthraquinone-based pigments, polycyclic quinone-based pigments; etc. Further, such materials may be used alone or in a combination of two or more.

The metal oxide 19 may use at least one selected from a group consisting of titanium oxide (TiO₂), niobium oxide, hafnium oxide, indium oxide, tin oxide, and zinc oxide. Titanium oxide is generally used as the metal oxide 19.

For example, the active layer 15 may include the dye 17 of Ru-dye, and the metal oxide 19 of titanium oxide (TiO₂).

The counter electrode 20 serves as an electrochromic function, an ion storage function, and a DSSC counter electrode function. The counter electrode 20 includes a second transparent substrate 21, a second transparent electrode layer 23, and an electrochromic layer 25, which have light transmittance. The second transparent electrode layer 23 is formed on a first surface of the second transparent substrate 21 facing the photoelectrode 10. Further, the electrochromic layer 25 is formed on the second transparent electrode layer 23.

The second transparent substrate 21 and the second transparent electrode layer 23 may use the same materials as the first transparent substrate 11 and the first transparent electrode layer 13, respectively.

The electrochromic layer 25 has a structure where a tungsten oxide (WO₃) layer 27 and a platinum (Pt) layer 29 are stacked. The tungsten oxide WO₃ layer 27 has the electrochromic function and the ion storage (cathode active material) function. In addition, the platinum (Pt) layer 29 has the DSSC counter electrode function, and induces a catalytic reaction of the DSSC.

The electrochromic layer 25 may be prepared by forming electro-depositing tungsten oxide (WO₃) on the first transparent electrode layer 13 to form the tungsten oxide (WO₃) layer 27, and then depositing platinum (Pt) on the tungsten oxide (WO₃) layer 27 by sputtering to form the platinum (Pt) layer 29.

Meanwhile, the electrochromic layer 25 according to an embodiment has, but not limited to, the structure where the platinum (Pt) layer 29 is formed on the tungsten oxide (WO₃) layer 27. For example, the electrochromic layer 25 may have a structure where the tungsten oxide (WO₃) layer 27 is formed on the platinum (Pt) layer 29.

The electrolyte 30 allows ions to be transferred between the photoelectrode 10 and the counter electrode 20. The electrolyte 30 includes a solvent and a lithium salt as an electrolyte. The electrolyte 30 performs charging/discharging based on insertion/desorption of lithium ions and oxidation/reduction of anions contained in the lithium salt.

Here, the solvent may include, but not limited to, ethylene carbonate (EC), ethyl methyl carbonate (EMC), propylene carbonate, butylene carbonate, vinylene carbonate, sulfolane, γ-butyrolactone, dimethyl carbonate, diethyl carbonate, 1,2-dimethoxy Ethane, or tetrahydrofuran.

The lithium salt may include at least one selected from a group consisting of LiI, LiCl, LiPF₆, LiBF₄, LiSbF₆, LiAsF₆, LiClO₄, LiCF₃SO₃, LiN(CF₃SO₂)₂, LiN(C₂F₅SO₂)₂, LiAlO₄, LiAlCl₄, LiN(CₓF₂ₓ₊₁SO₂)(C_{y}F2ₓ₊₁SO₂) (where, x and y are natural numbers), and LiSO₃CF₃.

Further, the sealing layer 40 is formed along the opposite edge portions of the photoelectrode 10 and the counter electrode 20, and prevents the electrolyte 30 filled between the photoelectrode 10 and the counter electrode 20 from leaking.

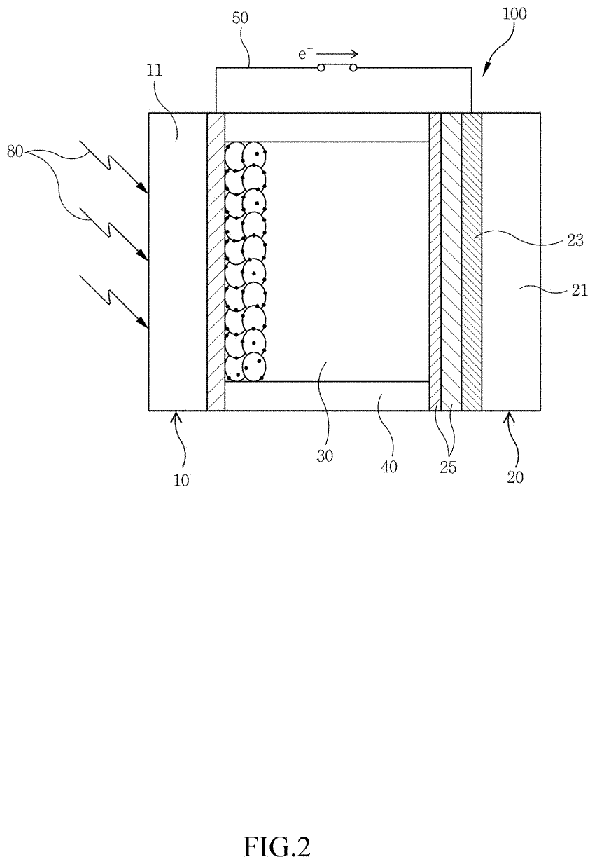

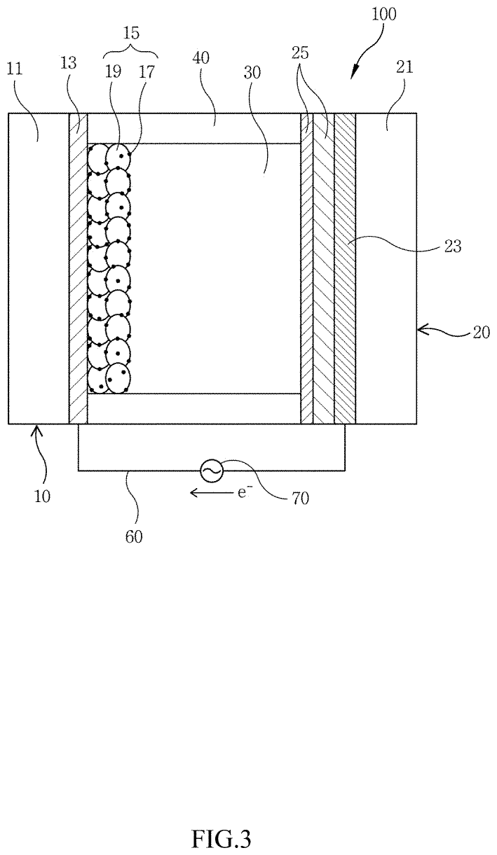

The all-in-one device 100 according to an embodiment may, as shown in FIGS. 2 and 3, perform the function of the DSSC, the function of the ECD that blocks light by discoloring an electrode with generated electrons, and the function of the LIB that stores generated electrons and uses the stored electrons again.

FIG. 2 is a view showing a state that the all-in-one device 100 of FIG. 1 generates and stores electric energy by receiving the solar energy 80 and performs an electrochromic operation.

Referring to FIG. 2, when the photoelectrode 10 and the counter electrode 20 are connected by an external charging circuit 50, the active layer 15 of the photoelectrode 10 generates electrons with the solar energy 80 incident on a second surface opposite to the first surface, and provides the generated electrons to the counter electrode 20 through the external charging circuit 50. The counter electrode 20 performs the electrochromic operation while the electrochromic layer 25 is storing the electrons.

FIG. 3 is a view showing a state that the all-in-one device 100 of FIG. 1 uses the stored electrical energy.

Referring to FIG. 3, when a load 70 is connected to the photoelectrode 10 and the counter electrode 20 through an external discharging circuit 60, the electrons stored in the electrochromic layer 25 are provided to the load 70 through the discharging circuit 60.

The all-in-one device 100 according to an embodiment includes the photoelectrode 10 used as the active layer 15 of the DSSC, the counter electrode 20 opposite to the photoelectrode 10 and used as the electrochromic layer 25, and the electrolyte 30 containing the lithium salt, so that the function of the DSSC that generates electrons by receiving the solar energy 80, the function of the ECD that blocks light by discoloring the electrode with generated electrons, and the function of the LIB that stores the generated electrons and uses the stored electrons again can be all implemented by one device.

The all-in-one device 100 according to an embodiment generates electrons through the photoelectrode 10, and blocks sunlight based on the electrochromism of the counter electrode 20 while storing the generated electrons in the counter electrode 20, thereby having a heat preservation effect.

Therefore, the all-in-one device 100 according to an embodiment produces electric energy by receiving the solar energy 80 and blocks ultraviolet rays to suppress heat loss during the day, and allows the stored electric energy to be used during the night, thereby maximizing an energy saving effect.

[Evaluation of Electrochromic, Solar Cell and Battery Performance of All-In-One Device]

To check the electrochromic, solar cell and battery characteristics of the all-in-one device 100 according to an embodiment, a sample according to an embodiment was prepared and then evaluated with respect to the electrochromic, solar cell and battery performance.

The Sample was Prepared as Follows.

As the substrates for the photoelectrode and the counter electrode, a glass substrate formed with an FTO layer on the surface thereof was used. As the active layer, titanium oxide (TiO₂) coated with Ru-dye on the surface thereof was used. The active layer was prepared by screen-printing titanium oxide (TiO₂) coated with the Ru-dye on the surface thereof on the FTO layer of the glass substrate.

As the electrochromic layer, a Pt30/a-WO₃ stacking layer was used. The electrochromic layer was prepared by forming an a-WO₃ layer by depositing amorphous tungsten oxide on the FTO layer of the glass substrate through the electro-deposition, and then forming a Pt30 layer by sputtering platinum (Pt) on the a-WO₃ layer for 30 seconds.

Further, to fill the electrolyte containing LiI between the photoelectrode and the counter electrode, the edge portions of the photoelectrode and the counter electrode were sealed with the sealing layer, thereby preparing the same according to an embodiment.

The sample was prepared to have an overall size of 2×2 cm, and have an inside size of the sealing layer of 1.3×1.3 cm. In other words, the sample was manufactured to have an active area of about 1 cm².

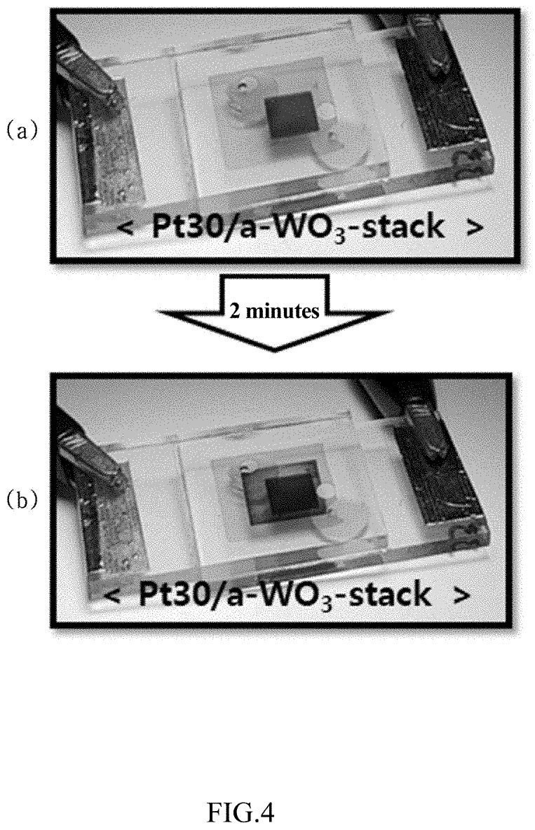

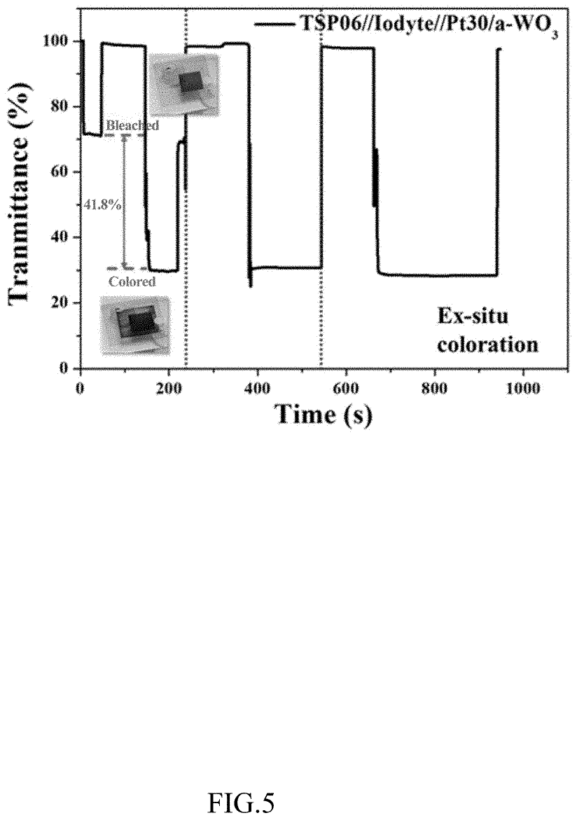

FIG. 4 is a photograph showing an electrochromic performance evaluation result of a photovoltaic-electrochromic-battery all-in-one device according to an embodiment of the disclosure. Further, FIG. 5 is a photograph showing an electrochromic performance evaluation result of a photovoltaic-electrochromic-battery all-in-one device according to an embodiment of the disclosure.

In FIG. 4, “Pt30/WO₃-stack” indicates the electrochromic layer of the sample. In FIG. 5, “TSP05” of “TSP06//Iodyte//Pt30/a-WO₃” indicates the active layer of the sample, “Iodyte” indicates the electrolyte that contains LiI, and “Pt30/a-WO₃” indicates the electrochromic layer.

“Ex-situ coloration” refers to an electrochromic performance evaluation method of the sample. In other words, the electrochromic performance evaluation of the sample was carried out in such a manner that the electrochromism was measured before irradiating the sample with sunlight, and then the electrochromism was measured after irradiating the sample with sunlight.

As shown in FIGS. 3 and 4, it is confirmed that the sample is discolored to change in transmittance to 41.8% within 2 minutes when irradiated only with sunlight without external electric power. In other words, it is understood that the sample functions as both the DSSC and the ECD.

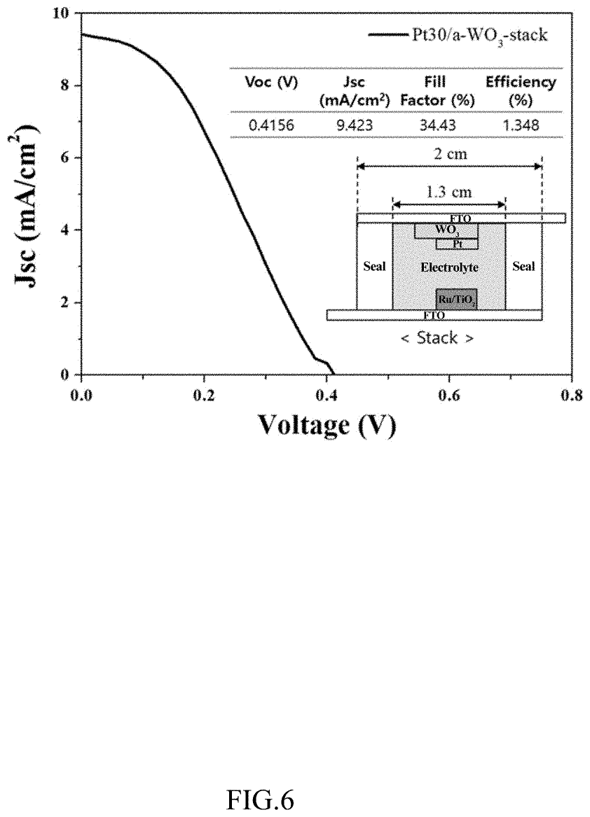

FIG. 6 is a graph showing a solar cell performance evaluation result of a photovoltaic-electrochromic-battery all-in-one device according to an embodiment of the disclosure.

Referring to FIG. 6, it was measured that the sample has a Jsc value of 9 mA/cm² and a solar efficiency of 1.35% as the solar cell. In other words, it will be understood that the sample functions as the DSSC.

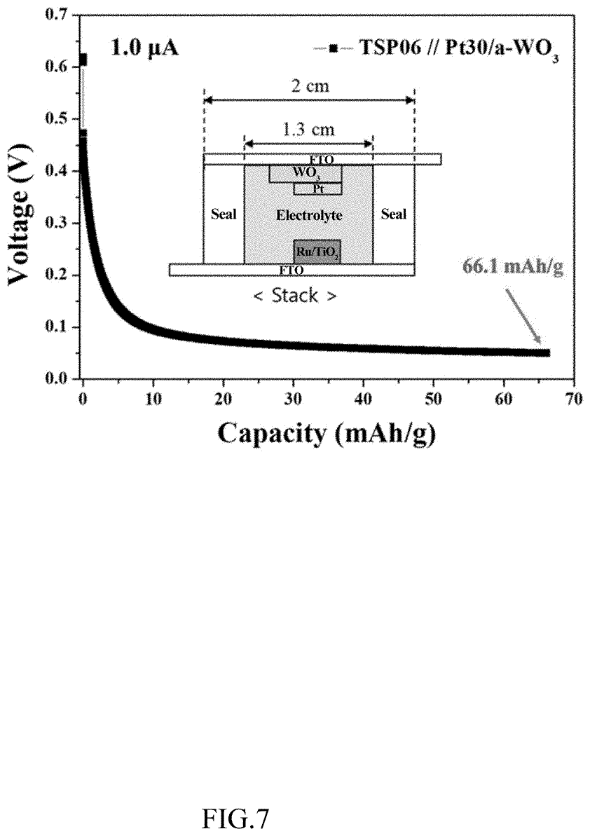

FIG. 7 is a graph showing a battery performance evaluation result of a photovoltaic-electrochromic-battery all-in-one device according to an embodiment of the disclosure.

Referring to FIG. 7, the sample was charged being irradiated with sunlight for 5 minutes and its discharging capacity was measured by applying a load of 1 μA by a constant current method. At this time, the sample functioned as a secondary battery having a discharging capacity per weight of about 66.1 mAh/g. In other words, it is confirmed that the sample functions as the LIB.

Thus, it will be understood that the sample having an active area of about 1 cm² has the performance of generating electrons by receiving the solar energy of 1sun as the function of the DSSC, consuming the generated electrons to have a discoloring rate of 41.8% as the function of the ECD, and storing a discharging capacity per unit weight of 66.1 mAh/g as the function of the battery.

In other words, the all-in-one device according to an embodiment allows the function of a dye-sensitized solar cell (DSSC) that generates electrons by receiving solar energy 80, the function of an electrochromic device (ECD) that blocks light by discoloring an electrode with generated electrons, and the function of a lithium secondary battery (LIB) that stores generated electrons and uses the stored electrons again to be all implemented by one device.

The all-in-one device according to an embodiment is applicable to, but not limited to, various products such as windows of buildings, which are highly likely to be exposed to sunlight, the glass of ships, aircraft, vehicles, etc., a variable transparent display, an active radio frequency identification (RFID) sensor, etc. For example, when the all-in-one device according to an embodiment is applied to the glass of a building as a smart window, the smart window may work to save energy by receiving the solar energy, and function as an operating power source by storing the energy in a usable form after sufficient discoloration is achieved. When the all-in-one device according to an embodiment is applied to vehicle sunroof glass as smart glass, the smart glass may work to block heat and ultraviolet rays without an external power source during daytime driving or outdoor parking, and the stored energy may be used as an emergency power source for the vehicle.

The all-in-one device according to the disclosure includes the photoelectrode used as the active layer of the DSSC, the counter electrode used as the electrochromic layer opposite to the photoelectrode, and the electrolyte containing the lithium salt so that the function of the DSSC that generates electrons by receiving solar energy, the function of the ECD that blocks light by discoloring an electrode with generated electrons, and the function of the LIB that stores generated electrons and uses the stored electrons again can be all implemented by one device.

The photovoltaic-electrochromic-battery all-in-one device according to the disclosure generates electrons through the photoelectrode, stores the generated electrons in the counter electrode, and blocks sunlight through the electrochromism of the counter electrode, thereby having a heat preservation effect.

Thus, the photovoltaic-electrochromic-battery all-in-one device can produce electric energy by receiving solar energy and blocks infrared rays to enhance an energy efficiency during the day, and allow the stored electric energy to be used to maximize an energy saving effect during the night.

The photovoltaic-electrochromic-battery all-in-one device according to the disclosure is appliable to various products such as windows of buildings, which are highly likely to be exposed to sunlight, the glass of ships, aircraft, vehicles, etc., a variable transparent display, an active radio frequency identification (RFID) sensor, etc.

Meanwhile, it should be understood that the embodiments disclosed herein are merely illustrative and are not intended to limit the scope of the invention. It will be apparent to those skilled in the art that various modifications can be made to the above-described exemplary embodiments of the present invention without departing from the spirit or scope of the invention.

DESCRIPTION OF REFERENCE NUMERALS

| | |
|---|---|
| 10: photoelectrode | 11: first transparent substrate |
| 13: first transparent electrode layer | |
| 15: active layer | 17: dye |
| 19: metal oxide | 20: counter electrode |
| 21: second transparent substrate | |
| 23: second transparent electrode layer | |
| 25: electrochromic layer | 27: WO₃ layer |
| 29: the platinum (Pt) layer | |
| 30: electrolyte | 40: sealing layer |
| 50: charging circuit | 60: discharging circuit |
| 70: load | 80: solar energy |
| 100: all-in-one device | |

1. A photovoltaic-electrochromic-battery all-in-one device comprising:
a photoelectrode formed with an active layer containing metal oxide coated with a dye on a first surface thereof;
a counter electrode opposite to the photoelectrode and formed with an electrochromic layer on a surface facing the active layer; and
an electrolyte containing a lithium salt filled between the photoelectrode and the counter electrode.

2. The photovoltaic-electrochromic-battery all-in-one device of claim 1, wherein the active layer of the photoelectrode generates electrons with solar energy incident on a second surface opposite to the first surface and provides the generated electrons to the counter electrode through an external charging circuit, and
the electrochromic layer of the counter electrode performs an electrochromic operation while storing the electrons.

3. The photovoltaic-electrochromic-battery all-in-one device of claim 2, wherein, upon connecting a load between the photoelectrode and the counter electrode through an external discharging circuit, the electrons stored in the electrochromic layer are provided to the load through the discharging circuit.

4. The photovoltaic-electrochromic-battery all-in-one device of claim 1, wherein the photoelectrode comprises:
a first transparent substrate having light transmittance;
a first transparent electrode layer formed on a first surface of the first transparent substrate facing the counter electrode; and
the active layer formed on the first transparent electrode layer.

5. The photovoltaic-electrochromic-battery all-in-one device of claim 4, wherein the active layer comprises Ru-dye as the dye, and titanium oxide (TiO₂) as the metal oxide.

6. The photovoltaic-electrochromic-battery all-in-one device of claim 5, wherein the active layer is formed by screen-printing the metal oxide coated with the dye on the first transparent electrode layer.

7. The photovoltaic-electrochromic-battery all-in-one device of claim 4, wherein the counter electrode comprises:
a second transparent substrate having light transmittance;
a second transparent electrode layer formed on a first surface of the second transparent substrate facing the photoelectrode; and
the electrochromic layer formed on the second transparent electrode layer.

8. The photovoltaic-electrochromic-battery all-in-one device of claim 7, wherein the electrochromic layer comprises a structure where a tungsten oxide (WO₃) layer and a platinum (Pt) layer are stacked.

9. The photovoltaic-electrochromic-battery all-in-one device of claim 8, wherein the electrochromic layer comprises:
the tungsten oxide (WO₃) layer formed being electro-deposited on the second transparent electrode layer; and
the platinum (Pt) layer formed being sputtered on the tungsten oxide (WO₃) layer.

10. The photovoltaic-electrochromic-battery all-in-one device of claim 1, wherein the lithium salt is at least one selected from the group consisting of LiI, LiCl, LiPF₆, LiBF₄, LiSbF₆, LiAsF₆, LiClO₄, LiCF₃SO₃, LiN(CF₃SO₂)₂, LiN(C₂F₅SO₂)₂, LiAlO₄, LiAlCl₄, LiN(CₓF₂ₓ₊₁SO₂)(C_{y}F2ₓ₊₁SO₂) (where, x and y are natural numbers), and LiSO₃CF₃.
